(19) United States
(12) Patent Application Publication
(10) Pub. No.: US 2015/0061783 A1
(43) Pub. Date: Mar. 5, 2015

(54) CRYSTAL CONTROLLED OSCILLATOR

(71) Applicant: NIHON DEMPA KOGYO CO., LTD., Tokyo (JP)

(72) Inventor: TOMOYA YORITA, SAITAMA (JP)

(21) Appl. No.: 14/467,061

(22) Filed: Aug. 25, 2014

(30) Foreign Application Priority Data
Aug. 27, 2013 (JP) 2013-175864

(51) Int. Cl. H03L 1/04; H03B 5/30

(52) U.S. Cl. CPC H03L 1/04; H03B 5/30
USPC 331/70

(57) ABSTRACT

A crystal controlled oscillator includes a crystal unit, an oscillator circuit, a temperature detector for crystal unit, a heating unit for crystal unit, a temperature detector for oscillator circuit, and a heating unit for oscillator circuit. The heating unit for crystal unit is configured to control an output of the crystal unit based on a temperature detected by the temperature detector for crystal unit to compensate the temperature of the atmosphere where the crystal unit is placed to be constant. An output of the heating unit for oscillator circuit is controlled independently from the heating unit for crystal unit based on a temperature detected by the temperature detector for oscillator circuit to compensate the temperature of the atmosphere where the oscillator circuit is placed to be constant.

### CROSS-REFERENCE TO RELATED APPLICATION

This application claims the priority benefit of Japanese application serial no. 2013-175864, filed on Aug. 27, 2013. The entirety of the above-mentioned patent application is hereby incorporated by reference herein and made a part of specification.

### BACKGROUND

1. Technical Field

This disclosure relates to a crystal controlled oscillator that detects a temperature of atmosphere where a crystal unit is placed and controls a heating unit based on a detection result of the temperature to make the temperature of atmosphere constant.

2. Description of the Related Art

A crystal controlled oscillator may be constituted as an oven controlled crystal oscillator (OCXO) when the crystal controlled oscillator is incorporated in an application requiring sufficiently high frequency stability. FIG. 8 illustrates an exemplary configuration of an OCXO 100 in a block diagram. A description will be given of the respective units of the OCXO 100 in the embodiment, and only an outline of the respective units will be described here in this section where appropriate. Japanese Unexamined Patent Application Publication No. 2013-51677 also discloses an OCXO having almost similar configuration.

In this OCXO 100, the temperature in an oven is calculated by using the difference between respective oscillation frequencies from: a first oscillator circuit 11 that oscillates a first crystal unit 10 disposed in the oven; and a second oscillator circuit 21 that oscillates a second crystal unit 20. Then, the OCXO 100 controls a crystal unit heater 52 such that the temperature in the oven will be kept at a Zero-Temperature Coefficient (ZTC) point of the first crystal unit.

The first the oscillator circuit 11 and the second oscillator circuit 21, for example, are parts of an integrated circuit (LSI). The ZTC point indicates a point of inflection plotted on a graph for the oscillation frequency of the crystal unit. The graph plots an amount of variation against the oscillation frequency at a reference temperature in the vertical axis, and a degree of temperature variation in the horizontal axis. Controlling the crystal unit heater so as to match the temperature of the crystal unit with the ZTC point can reduce the frequency variation against the temperature as much as possible. In the OCXO 100, an output from the first oscillator circuit 11, which is connected to the first crystal unit 10 under such temperature control, is supplied as a clock to the respective units of the LSI.

In this type of OCXO 100, however, a temperature deviation between the crystal unit and the oscillator circuit occurs in the case where the LSI that functions as the respective oscillator circuits 11 and 21 are disposed apart from the respective crystal units 10 and 20. Additionally, the respective oscillator circuits 11 and 21 have the variation characteristics of an output frequency against the temperature. Therefore, in the case where the temperature outside of the oven varies, the temperature of the LSI varies accordingly. This may cause the output frequency from the respective oscillator circuits 11 and 21 to vary. That is, a degradation of the temperature characteristics of the OCXO 100 may occur.

In the case where the OCXO 100 will be constituted so as to include the respective small-sized crystal units 10 and 20 and the significantly compact oven, the following method to address may be considered. The crystal unit and the LSI are arranged with a relatively close distance such that the temperature deviation between the above-described crystal units 10 and 20 and the LSI that functions as the oscillator circuits 11 and 21 can be relatively reduced. However, in the case such as, for example, where the OCXO 100 includes the large-sized oven and the respective crystal units 10 and 20 that are too large to be mounted in a single housing, the first and the second crystal units 10 and 20 and the LSI may not be able to be arranged so as to be capable of reducing the temperature deviation in the above manner. In such cases, the degradation of the temperature characteristics of the above-described OCXO 100 is especially concerned.

The disclosure has been made in view of the aforementioned problems, and an aim thereof is to provide a crystal controlled oscillator that allows obtaining oscillation output with high frequency stability, in the crystal controlled oscillator that detects a temperature of atmosphere where a crystal unit is placed and controls a heating unit based on a detection result of the temperature so as to make the temperature of atmosphere constant.

### SUMMARY

A crystal controlled oscillator according to the disclosure includes a crystal unit, an oscillator circuit, a temperature detector for crystal unit, a heating unit for crystal unit, a temperature detector for oscillator circuit, and a heating unit for oscillator circuit. The oscillator circuit is configured to oscillate the crystal unit. The temperature detector for crystal unit is configured to detect a temperature of atmosphere where the crystal unit is placed. The heating unit for crystal unit is configured to control an output of the crystal unit based on a temperature detected by the temperature detector for crystal unit to compensate the temperature of the atmosphere where the crystal unit is placed to be constant. The temperature detector for oscillator circuit is disposed separately from the temperature detector for crystal unit to detect a temperature of atmosphere where the oscillator circuit is placed. An output of the heating unit for oscillator circuit is controlled independently from the heating unit for crystal unit based on a temperature detected by the temperature detector for oscillator circuit to compensate the temperature of the atmosphere where the oscillator circuit is placed to be constant.

According to this disclosure, the crystal controlled oscillator includes the temperature detector for oscillator circuit and the heating unit for oscillator circuit. The temperature detector for oscillator circuit is disposed separately from the temperature detector for crystal unit. The temperature detector for oscillator circuit is configured to detect a temperature of atmosphere where the oscillator circuit is placed. The heating unit for oscillator circuit is controlled independently of the heating unit for crystal unit based on a detection result of the temperature detector for oscillator circuit. Therefore, the temperature variations of the oscillator circuit can be controlled, and the oscillation frequency variations that are outputted from the oscillator circuit can be restricted even if the oscillator circuit and the crystal unit are located far apart one another. Additionally, this eliminates the need for locating the oscillator circuit and the crystal unit in close as arranging these units, and provides a greater flexibility of configuring the crystal controlled oscillator.

### BRIEF DESCRIPTION OF THE DRAWINGS

FIG. 1 is a block diagram illustrating an OCXO according to this disclosure.

FIG. 2 is a longitudinal cross-sectional side view illustrating the OCXO.

FIG. 3 is a block diagram illustrating a heater control circuit for oscillator circuit disposed in the OCXO.

FIG. 4 is a graph schematically illustrating a temperature control method.

FIG. 5 is a graph schematically illustrating the temperature control method.

FIG. 6 is an explanatory drawing illustrating a state where switches of the heater control circuit for the oscillator circuit are operated to switch.

FIG. 7 is a longitudinal cross-sectional side view illustrating another example of a configuration of an OCXO.

FIG. 8 is a block diagram illustrating a conventional OCXO.

### DETAILED DESCRIPTION

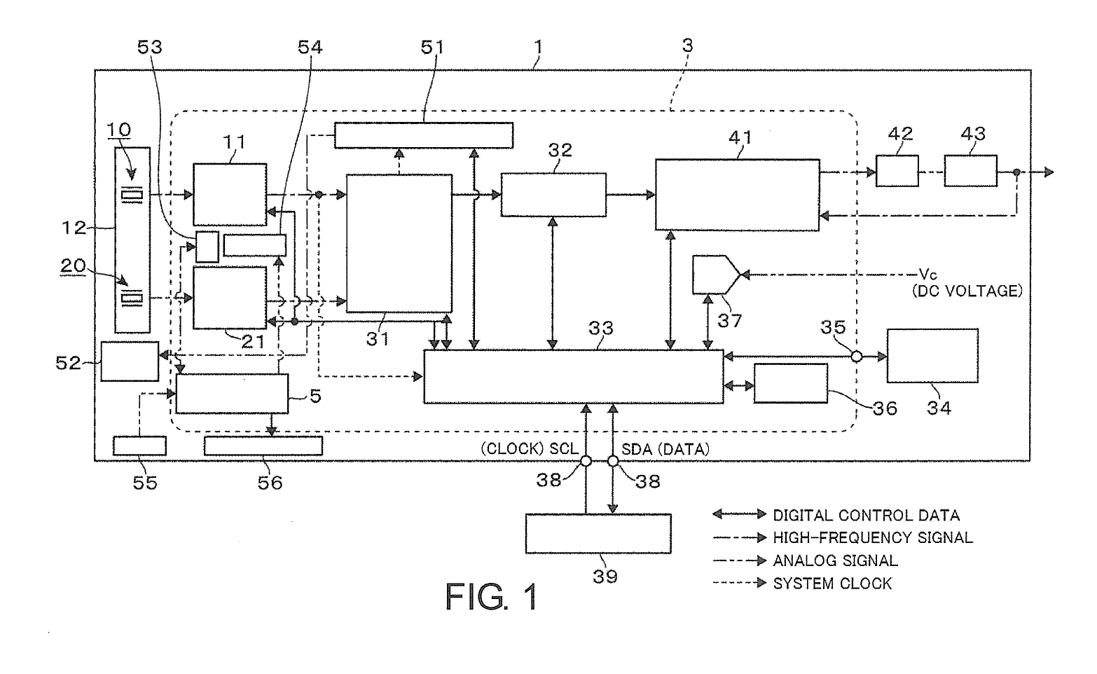

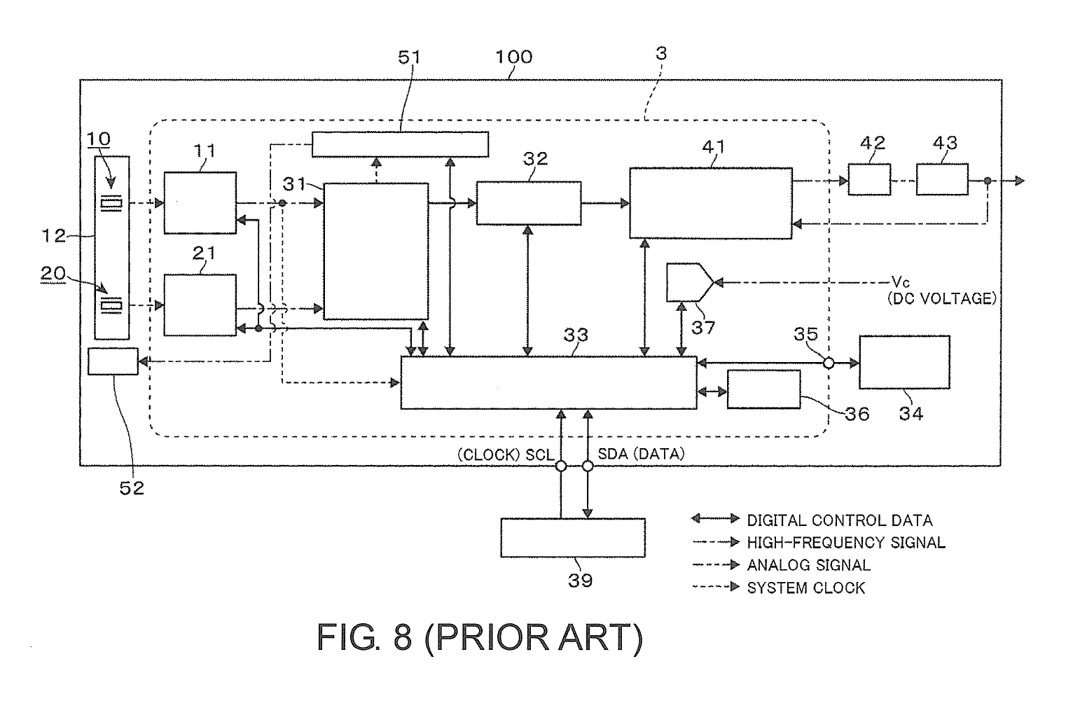

An OCXO 1, which is an embodiment of a crystal controlled oscillator according to the disclosure, will be described. FIG. 1 illustrates a block diagram of the OCXO 1. In this a block diagram, a signal flow of digital control data, in a state where the operations for setting and reading/writing of registers of the respective circuits in the OCXO 1 are performed, is illustrated by a solid line with arrows. A one dot chain line with an arrow illustrates a flow direction of a high-frequency signal. A two-dot chain line with an arrow illustrates a flow direction of an analog signal. Lastly, a dotted line with an arrow illustrates a flow direction of a system clock signal. An OCXO 100 in FIG. 8, as described in the section of DESCRIPTION OF THE RELATED ART, also illustrates each signal flow with using the respective arrows in the same manner as the OCXO 1 in FIG. 1.

The OCXO 1 includes a first crystal unit 10 and a second crystal unit 20. The crystal units 10 and 20 are each constituted of an AT-cut crystal element and an excitation electrode. In this example, the first crystal unit 10 and the second crystal unit 20 are housed adjacent to each other in a common case 12 so as to be displaced at mutually equal ambient temperature. The first crystal unit 10 is connected to a first oscillator circuit 11 disposed outside of the case 12. Similarly, the second crystal unit 20 is connected to a second oscillator circuit 21 disposed outside of the case 12.

In the subsequent stage sides of the first oscillator circuit 11 connected to the first crystal unit 10 and the second oscillator circuit 21 connected to the second crystal unit 20; a frequency counter 31, a temperature correction and frequency calculation unit 32, a PLL circuit unit 41, a low-pass filter (LPF) 42, and a voltage controlled crystal oscillator (VCXO) 43 are connected. The PLL circuit unit 41 treats an oscillation output from the first oscillator circuit 11 as the clock signal. The PLL circuit unit 41 converts a signal corresponding to a phase difference between a pulse signal and a feedback pulse from the VCXO 43 into the analog signal, integrates the analog signal, and outputs the result to the low-pass filter 42. The pulse signal is generated based on a frequency setting signal, which is a digital value. The output from the LPF42 controls the output of the VCXO 43, which is an oscillating unit. The output of the VCXO 43 is the oscillation output of the OCXO 1.

A value corresponding to a frequency difference AF between the oscillation output f1 from the first oscillator circuit 11 and the oscillation output f2 from the second oscillator circuit 21 corresponds to a temperature of atmosphere where the crystal units 10 and 20 are placed. This value is referred to as a temperature detection value. For convenience of explanation, the oscillation outputs f1 and f2 also respectively represent the oscillation frequencies of the first oscillator circuit 11 and the second oscillator circuit 21. The frequency counter 31, which is a differential signal output unit, extracts a value of {(f2−f1)/f1}−{(f2r−f1r)/f1r} in this example. This value corresponds to the temperature detection value in a proportional relationship to a temperature. The values f1r and f2r are respectively the oscillation frequency of the first oscillator circuit 11 and the oscillation frequency of the second oscillator circuit 21 at a reference temperature, for example, 25° C.

The temperature correction and frequency calculation unit 32, which is a control signal output unit, calculates a frequency correction value based on a relationship between a detection result of a temperature and a pre-established frequency correction value, and adds the frequency correction value and the predetermined frequency setting value to set the frequency setting signal (control signal). That is, a signal corresponding to the frequency correction value with respect to f1r is set based on the relationship between change from f1r of f1 and the signal corresponding to the difference between f1 and f2. The relationship between the temperature detection value and the frequency correction value, and the frequency setting value are stored in a digital control circuit 33. The frequency correction value is a value for compensating change when the temperature of the first crystal unit 10 is changed from a target temperature, that is, change in temperature of the clock signal.

For example, assuming a (f2−f2r)/f2r=OSC2, (f1−f1r)/f1r=OSC1, when producing the crystal unit, a relationship between (OSC2-OSC1) and the temperature is obtained through actual measurement, and from the actual measurement data, a curve of compensation frequency cancelling an amount of the frequency variation with respect to the temperature is derived, and coefficients of the ninth-order polynomial approximate expression are derived through a least squares method. Further, the coefficients of the polynomial approximate expression are previously stored in the digital control circuit 33, and the temperature correction and frequency calculation unit 32 performs calculation processing of the correction value by using these coefficients of the polynomial approximate expression. Consequently, a frequency of a clock is stabilized with respect to the temperature variation, and accordingly, an output frequency from the VCXO 43 is stabilized. That is, the OCXO 1 is also constituted as a Temperature Compensated Crystal Oscillator (TCXO). So to speak, the OCXO 1 is constituted as an apparatus with dual temperature control that can stabilize an output with high accuracy.

In FIG. 1, reference numeral 34 denotes an external memory consisted of electrically erasable programmable read-only memories (EEPROMs). Reference numeral 35 denotes a connecting terminal that connects the external memory 34 to a digital signal processing unit 3 (described below). The coefficients of the polynomial approximate expression and the frequency setting value are fetched into the register of the digital control circuit 33 from the external memory 34 when a power source of the OCXO 1 is turned on. Reference numeral 36 denotes an internal memory that stores an initial parameter for the respective units of the digital signal processing unit 3 to function. The digital control circuit 33 causes the initial parameter to be set in the respective circuits of the digital signal processing unit 3 when the power source of the OCXO 1 is turned on, thus enabling a successive functions of the respective circuits. Reference numeral 37 denotes an analog-digital converter that converts an analog DC voltage signal Vc, which is supplied to the digital signal processing unit 3, into a digital DC voltage signal. The output of the first oscillator circuit 11 is supplied as the system clock to the digital control circuit 33 as well.

Reference numerals 38 and 38 denote the portions that serve a role of connecting the digital control circuit 33 with an interface circuit included in an external computer 39 via an Inter-Integrated Circuit (I²C) bus. Operators of OCXO 1 can modify each data in the register included in the digital control circuit 33 through the external computer 39. For example, the operators can change the predetermined frequency setting value to change the output frequency of the OCXO

A crystal unit heater control circuit 51 is disposed in the OCXO 1 for controlling the temperature based on the detection result of the temperature such that the temperature of the atmosphere where the crystal units 10 and 20 are placed becomes the setting temperature. The crystal unit heater control circuit 51 supplies an electric power to a crystal unit heater 52 that is a heating unit for crystal unit, corresponding to the temperature detection value (digital value) output from the frequency counter 31 and the predetermined temperature setting value output from the digital control circuit 33. The more the electric power is supplied, the higher an amount of the heat generation from the crystal unit heater 52 becomes. Then, the crystal units 10 and 20 are compensated for temperature such that the temperature of the first crystal unit 10 is kept at the ZTC point.

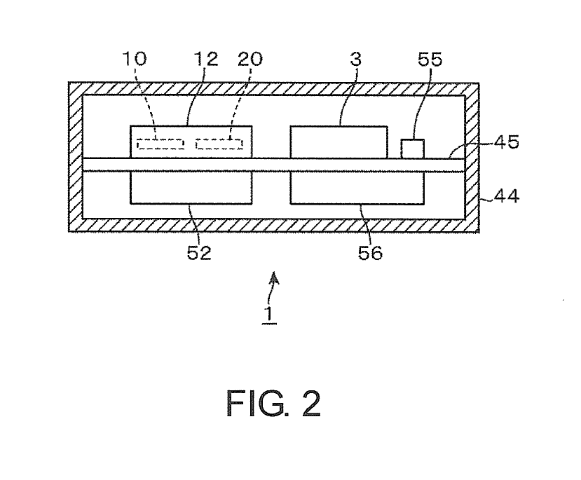

Hereafter, a description will be given with reference to the FIG. 2 as well, which is a longitudinal cross-sectional side view illustrating the OCXO 1. The OCXO 1 includes an oven 44 and a substrate 45 disposed in the oven 44. For example, the case 12 including the crystal units 10 and 20 is disposed on the front side (one surface) of a substrate 45, and the crystal unit heater 52 is disposed on the back side of the substrate 45 so as to overlap with the case 12. However, the crystal units 10 and 20 are not necessarily stored in the common case 12. The integrated circuit (LSI) that constitutes the digital signal processing unit 3 is disposed on the surface of the substrate 45 being far apart from the case 12. The oscillator circuits 11 and 21, the frequency counter 31, the temperature correction and frequency calculation unit 32, the PLL circuit unit 41, the crystal unit heater control circuit 51, the digital control circuit 33, the analog-digital converter 37, and the internal memory 36, as above described, are included in the digital signal processing unit 3, which is the integrated circuit. Thus, the digital signal processing unit 3 and the case 12 surrounding the crystal units 10 and 20 are both disposed in the internal space of the oven 44.

Referring back to FIG. 1, additionally, an oscillator circuit (OSC) heater control circuit 5 (hereinafter referred to as OSC heater control circuit), an internal temperature sensor 53, which is a first temperature sensor, an OSC internal heater 54, which is a first heating element, an external temperature sensor 55, which is a second temperature sensor, an OSC external heater 56, which is a second heating element, are disposed in OCXO 1. The internal temperature sensor 53 and the external temperature sensor 55 each detect the ambient temperature of the digital signal processing unit 3 and each output an analog voltage signal corresponding to this detection temperature to the OSC heater control circuit 5. The above-described temperature sensors 53 and 55, which constitute the temperature detector for oscillator circuit, each consist of a transistor and a diode or similar.

One output voltage of the internal temperature sensor 53 and the external temperature sensor 55 is employed for detecting the ambient temperature of the digital signal processing unit 3, as described below. One of the OSC internal heater 54, which constitutes the heating unit for oscillator circuit, and the OSC external heater 56 is employed for making the ambient temperature of the digital signal processing unit 3 constant. In this example, the OSC internal heater 54 controls the ambient temperature where employing the output of the internal temperature sensor 53, and the OSC external heater 56 controls the ambient temperature where employing the output of the external temperature sensor 55.

The internal temperature sensor 53, the OSC internal heater 54, and the OSC heater control circuit 5 are included in the digital signal processing unit 3. As illustrated in FIG. 2, the external temperature sensor 55 is disposed on the front side of the substrate 45 adjacent to the digital signal processing unit 3. The OSC external heater 56, for example, is disposed on the back side (another side) of the substrate 45 so as to overlap with the digital signal processing unit 3.

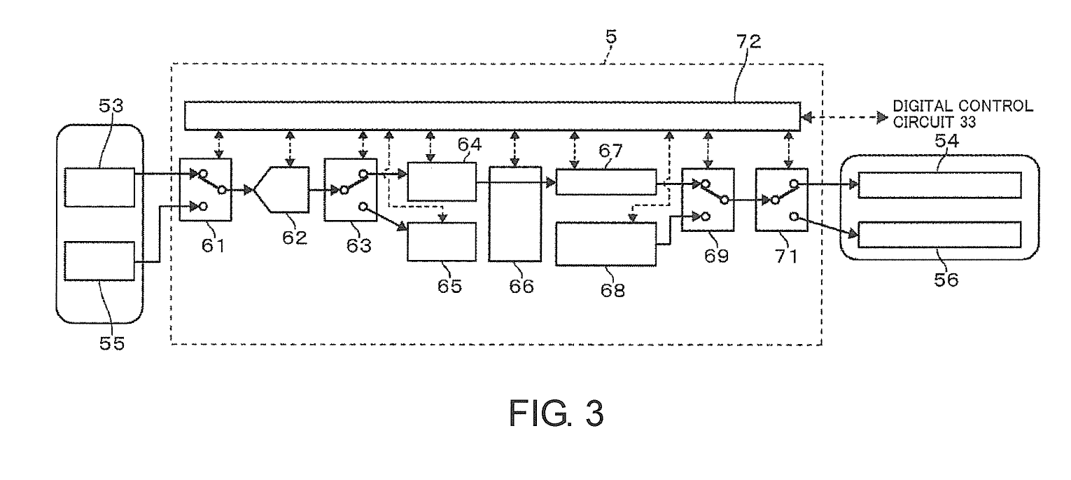

FIG. 3 illustrates an outline structure of the OSC heater control circuit 5. A switch 61 is disposed so as to supply one output of the internal temperature sensor 53 and the external temperature sensor 55 to the subsequent stages. An analog-digital converter (ADC) 62 is disposed in a position after the switch 61. A switch 63, which is disposed in a position after the ADC 62, the output supplied from the preceding stages is switched to either one of an internal temperature memory 64 and an external temperature memory 65 to be output. A switch 66 is disposed in a position after the stages of the internal temperature memory 64 and the external temperature memory 65. A PI control circuit 67 and a correction circuit 68 are disposed in a position after the switch 66.

The switch 66 supplies one output of the internal temperature memory 64 and the external temperature memory 65 to either one of the PI control circuit 67 and the correction circuit 68. However, regarding the switch 66, FIG. 3 illustrates a state where the internal temperature memory 64 and the PI control circuit 67 are connected. That is, the switch 66 is constituted so as to be capable of switching the following states: the state of the above-described connection between the internal temperature memory 64 and the PI control circuit 67; the state of connection between the internal temperature memory 64 and the correction circuit 68; the state where the external temperature memory 65 is connected with the PI control circuit 67; the state where the external temperature memory 65 is connected with the correction circuit 68.

A switch 69 is disposed in a position after the PI control circuit 67 and the correction circuit 68, in which switching is performed so as to be connected either one of the PI control circuit 67 and the correction circuit 68 to the subsequent stages. A switch 71 is disposed in a position after the switch 69. The above-described the OSC internal heater 54 and the OSC external heater 56 are disposed in a position after the switch 71. The switch 71 is operated to switch such that the electric power supplied from the PI control circuit 67 or the correction circuit 68 is output to either one of the OSC internal heater 54 and the OSC external heater 56. The more the electric power is supplied, the higher an amount of the heat generation from the OSC internal heater 54 and the OSC external heater 56 becomes.

When controlling the ambient temperature of the digital signal processing unit 3 based on the output of the internal temperature sensor 53, the respective switches disposed in the internal temperature sensor 53, the internal temperature memory 64, and the OSC internal heater 54 are operated to switch such that these units are successively connected to one another. When controlling the ambient temperature of the digital signal processing unit 3 based on the output of the external temperature sensor 55, the respective switches disposed in the external temperature sensor 55, the external temperature memory 65, and the OSC external heater 56 are operated to switch such that these units are successively connected to one another. In addition, depending on a user's desired temperature control method, the connections are performed with the respective switches such that one of the PI control circuit 67 and the correction circuit 68 is interposed between the temperature memories 64 and 65 and the heaters 54 and 56, which are respectively connected.

The OSC heater control circuit 5 includes an internal control circuit 72 that functions as a selection mechanism. The internal control circuit 72 controls the behavior and switching of the respective circuits in response to the control signal from the digital control circuit 33. The operators of OCXO 1 can control the behavior of the OSC heater control circuit 5 through the external computer 39 since the behavior of the digital control circuit 33 can be controlled through the external computer 39, as described above.

Both signal voltage input from either temperature sensor 53 or 55 and the correspondence relationship with the detection temperature are stored in the respective internal temperature memory 64 and the external temperature memory 65. The signal that corresponds to the detection temperature based on the correspondence relationship is output to either one of the PI control circuit 67 or the correction circuit 68.

The PI control circuit 67 performs a proportional-plus-integral control (PI control) to control the OSC internal heater 54 or the OSC external heater 56 such that the constant ambient temperature of the digital signal processing unit 3 is kept. In the PI control circuit 67, based on the temperature signal input from the respective temperature memories 64 and 65, the temperature deviation ((X−Y)° C.) between the target setting temperature (X° C.) of the ambient temperature and the detection temperature (Y° C.) by the respective temperature sensors 53 and 55 is calculated. Subsequently based on this temperature deviation, an amount of the electric power supplied to the heater 54 or 56 is calculated. And then, this calculated electric power is supplied to the heater 54 or 56.

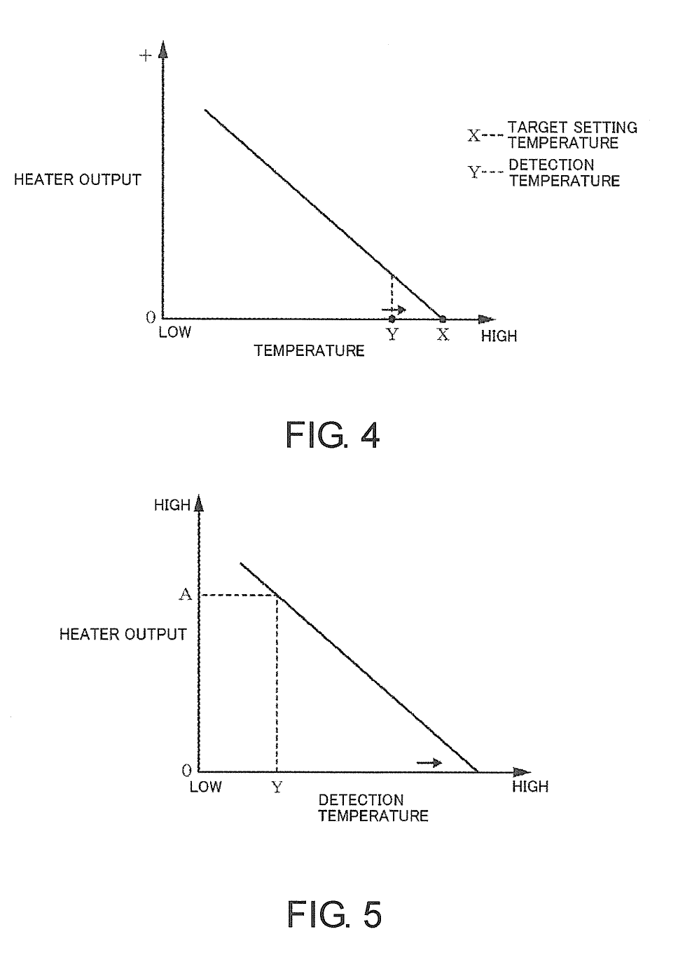

FIG. 4 is a graph conceptually illustrating for representing a state where the temperature deviation causes the heater output to be set. As illustrated in FIG. 4, the amount of the heater output decreases as the detection temperature Y° C. approaches the target setting temperature X° C. In practice, the heater output is controlled by PI control as described above, and the detection temperature Y° C. is controlled so as to be adjusted to be matched with the target setting temperature X° C.

The correction circuit 68 stores a table specifying the correspondence relationship between the detection temperature Y° C. and the electric power supplied to the heater (heater output). The heater output corresponding to the detection temperature is read from the table. This read output is supplied from the correction circuit 68 to the heater 54 or 56. FIG. 5 illustrates one exemplary correspondence relationship specified in the table on the graph for ease of description. As illustrated in FIG. 5, in the case where employing the correction circuit 68, unlike the case where employing the PI control circuit 67, the heater electric power (referred to as A, unit: W) corresponding to the detection temperature Y° C. is read from the table without computing (X−Y)° C., and this readout electric power is supplied to the heater 54 or 56.

The correction circuit 68 may include a computation formula of first order to nth order (N is an integer equal to or greater than two) related to the detection temperature Y° C., instead of including the table. The value of the computation formula is an approximation of the heater output value for allowing the ambient temperature of the digital signal processing unit 3 to reach the target setting temperature X° C. The correction circuit 68 may calculate the approximation based on this computation formula and the detection temperature and allow the electric power corresponding to the value calculated to be supplied to the heater 54 or 56.

Controlling the output of the heaters 54 and 56 with the above-described correction circuit 68 or the PI control circuit 67 thermally connects the temperature sensor 53 or 55 with the heater 54 or 56, respectively. That is, the output of the heater varies in response to the change in the detection temperature by the temperature sensor.

For example, the parameter for controlling the operations of the respective switches in the OSC heater control circuit 5 is stored in the external memory 34. When the power source of the OCXO 1 is turned on by the operators, the parameter is read out to the digital control circuit 33. Subsequently, the digital control circuit 33 sends the control signal to the OSC heater control circuit 5 based on the relevant parameter. Switching operations of the respective switches in the OSC heater control circuit 5 are controlled based on the control signal. Here, as illustrated in FIG. 3, one example will be described below as the internal temperature sensor 53, the internal temperature memory 64, the PI control circuit 67, and the OSC internal heater 54 are successively connected to one another.

As the external temperature of the OCXO 1 decreases, a temperature of atmosphere where the digital signal processing unit 3 is placed (ambient temperature of the digital signal processing unit 3) and a temperature of atmosphere where the crystal units 10 and 20 are placed (ambient temperature of the crystal units 10 and 20) decrease lower than the setting temperature. For example, the temperature detection value {(f2−f1)/f1}−{(f2r−f1r)/f1r} from the frequency counter 31 that constitutes the temperature detector for crystal unit decreases. This causes the electric power supplied from the crystal unit heater control circuit 51 to the crystal unit heater 52, which constitutes the heating unit for crystal unit, to increase. As a result, the ambient temperature of the crystal units 10 and 20 increases and is compensated so as to be the above-described setting temperature.

While the crystal units 10 and 20 are compensated for temperature as described above, the ambient temperature of the digital signal processing unit 3 detected by the internal temperature sensor 53 decreases, and accordingly the electric power supplied from the PI control circuit 67 to the OSC internal heater 54 increases. As a result, the electric power supplied to the OSC internal heater 54 increases, and the ambient temperature of the digital signal processing unit 3 is compensated so as to become the above-described setting temperature.

As the external temperature of the OCXO 1 increases, the respective ambient temperatures of the digital signal processing unit 3 and the crystal units 10 and 20 increase higher than the setting temperature. For example, the temperature detection value {(f2−f1)/f1}−{(f2r−f1r/f1r} from the frequency counter 31 increases, and this causes the electric power supplied from the crystal unit heater control circuit 51 to the crystal unit heater 52 to decrease. As a result, the ambient temperature of the crystal units 10 and 20 decreases and is compensated so as to become the above-described setting temperature.

On the other hand, the ambient temperature of the digital signal processing unit 3 detected by the internal temperature sensor 53 increases, and accordingly the electric power supplied from the PI control circuit 67 to the OSC internal heater 54 decreases. As a result, the electric power supplied to the OSC internal heater 54 decreases, and the ambient temperature of the digital signal processing unit 3 is compensated so as to become the setting temperature.

The respective ambient temperatures of the crystal units 10 and 20 and the digital signal processing unit 3 including the oscillator circuits 11 and 21 are compensated so as to be kept at a constant temperature. This causes an oscillation output frequency from the oscillator circuits 11 and 21 to stabilize. Consequently, the variations of the clock signal supplied to the PLL circuit unit 41 can be controlled, and moreover, the frequency correction value computed by the temperature correction and frequency calculation unit 32 is calculated with high accuracy. As a result, this ensures a stable oscillation output frequency of the OCXO 1.

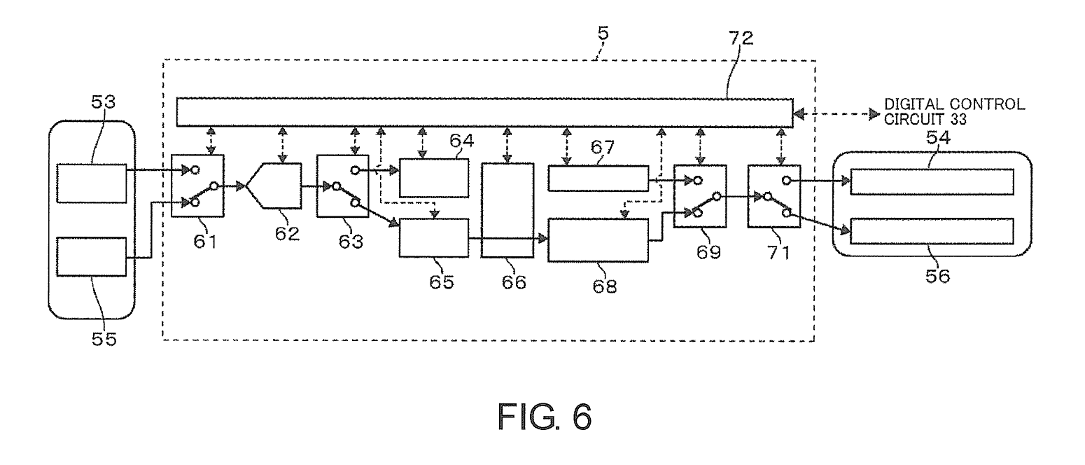

With the OCXO 1 in operation, for example, user's modifying the parameter in the register of the digital control circuit 33 through the external computer 39 changes the respective switches of the OSC heater control circuit 5. FIG. 6 illustrates an example of a state where the respective switches are changed from the state of FIG. 3 and the respective units of the external temperature sensor 55, the external temperature memory 65, the correction circuit 68, and the OSC external heater 56 are successively connected to one another. Thus, in the case where the connection is thus switched, the temperature control is performed as is the case in connecting respective circuits in a manner such as above-described FIG. 3 except that the ambient temperature of the digital signal processing unit 3 is detected by the external temperature sensor 55 instead of the internal temperature sensor 53, the output to the heater is controlled by the correction circuit 68 instead of the PI control circuit 67, and the above-described ambient temperature is heated by the OSC external heater 56 instead of the OSC internal heater 54.

The ambient temperatures of the crystal units 10 and 20 and the digital signal processing unit 3 are each independently controlled so as to become its corresponding setting temperature. Accordingly, even if the external temperature of the OCXO 1 varies, the respective crystal units 10 and 20 and the digital signal processing unit 3 are compensated for temperature with high accuracy, and the output frequency from the oscillator circuits 11 and 21 is stabilized. As a result, the oscillation output frequency from the OCXO 1 is stabilized. In addition, this eliminates the need for disposing the crystal units 10 and 20 adjacent to the oscillator circuits 11 and 21 respectively for the temperatures of the oscillator circuits 11 and 21 to change along with the crystal units 10 and 20 respectively if the crystal unit heater 52 causes the temperature of the crystal units 10 and 20 to change. Therefore, a layout with a greater flexibility can be provided regarding the location between the crystal units 10 and 20 in the substrate and the digital signal processing unit 3 including the oscillator circuits 11 and 21.

While in the above-described configuration example, a set of the internal temperature sensor 53 and the OSC internal heater 54 or a set of the external temperature sensor 55 and the OSC external heater 56 can be selected to use, only one of the sets may be disposed in the OCXO 1. In the case where only the set of the internal temperature sensor 53 and the OSC internal heater 54 is disposed, the constitution of the apparatus can be simplified. In the case where only the set of the external temperature sensor 55 and the OSC external heater 56 is disposed, the OSC external heater 56 is disposed outside of the LSI. Thus, any arrangement can be applied regardless of the LSI size, and accordingly the apparatus can be constituted such that the relatively large amount of the output can be obtained. In other words, a temperature range of feasibly temperature-controlled and a distance range from each heater within the oven are enlarged.

Likewise, only one circuit of the PI control circuit 67 and the correction circuit 68 may be disposed in the OCXO 1. In addition, the output of the OSC internal heater 54 may be controlled based on the detection temperature of the external temperature sensor 55 while the temperature of the OSC external heater 56 may be controlled based on the detection temperature of the internal temperature sensor 53.

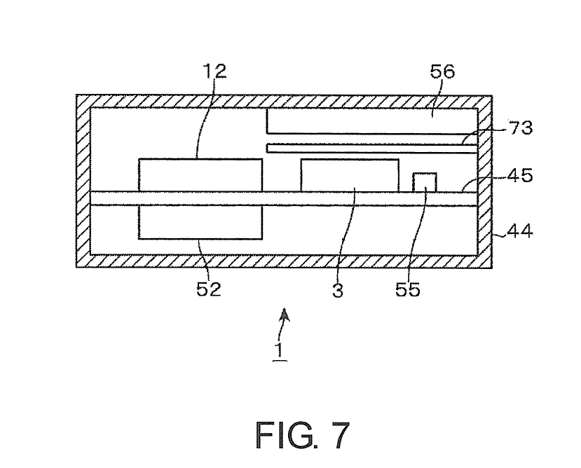

The arrangement of the respective circuits within the oven is not limited to the configuration of FIG. 2, and may also include the configuration as illustrated in FIG. 7. FIG. 7 illustrates, unlike the example in FIG. 2, a state where the OSC external heater 56 is disposed over the digital signal processing unit 3 and the external temperature sensor 55. A heat transfer member 73 made of such as metal is disposed between: the heater 56; and the digital signal processing unit 3 and the temperature sensor 55 for increasing the thermal conductivity in transferring heat from the heater 56 to the digital signal processing unit 3 and the temperature sensor 55. The example in FIG. 7 illustrates a state where the heat transfer member 73 is disposed so as to be apart from both the sides of the heater 56 and the digital signal processing unit 3 and to be disposed between above respective units.

In the above-described example, the second crystal unit 20, the second oscillator circuit 21, and the frequency counter 31 are constituted as the temperature sensor in order to detect the ambient temperature of the first crystal unit 10 with high accuracy. Instead of including the second crystal unit 20 and the second oscillator circuit 21, a thermistor or similar member may be included to be employed as the temperature sensor that measures the ambient temperature of the first crystal unit 10. In this case, the output of the first the oscillator circuit 11 serves as the output of the OCXO as it is.

What is claimed is:

1. A crystal controlled oscillator, comprising:
a crystal unit;
an oscillator circuit configured to oscillate the crystal unit;
a temperature detector for crystal unit configured to detect a temperature of atmosphere where the crystal unit is placed;
a heating unit for crystal unit configured to control an output of the crystal unit based on a temperature detected by the temperature detector for crystal unit to compensate the temperature of the atmosphere where the crystal unit is placed to be constant;
a temperature detector for oscillator circuit disposed separately from the temperature detector for crystal unit to detect a temperature of atmosphere where the oscillator circuit is placed; and
a heating unit for oscillator circuit whose output is controlled independently from the heating unit for crystal unit based on a temperature detected by the temperature detector for oscillator circuit to compensate the temperature of the atmosphere where the oscillator circuit is placed to be constant.

2. The crystal controlled oscillator according to claim 1, wherein
the atmosphere where the oscillator circuit is placed and the atmosphere where the crystal unit is placed are an atmosphere in an oven that surrounds the oscillator circuit and the crystal unit.

3. The crystal controlled oscillator according to claim 1, wherein
the oscillator circuit is included in an integrated circuit, and
the integrated circuit includes the heating unit for oscillator circuit and the temperature detector for oscillator circuit.

4. The crystal controlled oscillator according to claim 1, wherein
the oscillator circuit is included in an integrated circuit, and
the integrated circuit includes a first heating element, wherein
the crystal controlled oscillator further comprising:
a second heating element disposed at an outside of the integrated circuit; and
a selection mechanism configured to select any one of the first heating element and the second heating element for use as the heating unit for oscillator circuit.

5. The crystal controlled oscillator according to claim 4, wherein
an operation of the selection mechanism is controlled by a computer connected to the crystal controlled oscillator.

6. The crystal controlled oscillator according to claim 1, wherein
the oscillator circuit is included in an integrated circuit, and
the integrated circuit includes a first temperature sensor, wherein
the crystal controlled oscillator further comprising:
a second temperature sensor disposed at an outside of the integrated circuit, and
a selection mechanism configured to select any one of the first temperature sensor and the second temperature sensor for use as the temperature detector for oscillator circuit.

7. The crystal controlled oscillator according to claim 6, wherein
an operation of the selection mechanism is controlled by a computer connected to the crystal controlled oscillator.

8. The crystal controlled oscillator according to claim 1, wherein
the crystal unit includes a first crystal unit and a second crystal unit,
the oscillator circuit includes a first oscillator circuit and a second oscillator circuit, wherein the first oscillator circuit is configured to oscillate the first crystal unit, and the second oscillator circuit is configured to oscillate the second crystal unit,
the heating unit for crystal unit is configured to heat the first crystal unit and the second crystal unit, and
the heating unit for oscillator circuit is configured to heat the first oscillator circuit and the second oscillator circuit.

9. The crystal controlled oscillator according to claim 8, further comprising:
a differential signal output unit configured to output a differential signal corresponding to a difference between an oscillation output fl of the first oscillator circuit and an oscillation output f2 of the second oscillator circuit;
a control signal output unit configured to output a control signal to reduce an influence based on a temperature characteristic of the oscillation output f1 based on the differential signal; and
an oscillating unit whose oscillation output is controlled based on the control signal.

10. The crystal controlled oscillator according to claim 9, wherein
the control signal is configured to reduce the influence based on the temperature characteristic of the oscillation output f1, and the control signal is a signal corresponding to a frequency correction value with respect to the oscillation output f1 at a reference temperature based on a relationship between: change of the oscillation output f1 from a f1 value at the reference temperature, and a signal corresponding to a difference between the oscillation output f1 and the oscillation output f2.

11. The crystal controlled oscillator according to claim 1, wherein
the oscillator circuit is disposed at one surface of a substrate, and
the heating unit for oscillator circuit is disposed at another surface of the substrate so as to be overlapped with the oscillator circuit.

12. The crystal controlled oscillator according to claim 1, wherein
the oscillator circuit is disposed at a substrate,
the heating unit for oscillator circuit is disposed above the oscillator circuit, and
a heat transfer member made of metal is disposed away from the oscillator circuit and the heating unit for oscillator circuit so as to be disposed between the oscillator circuit and the heating unit for oscillator circuit, and the heat transfer member is configured transmit heat from the heating unit for oscillator circuit to the oscillator circuit.
